(19) United States
(12) Patent Application Publication
(10) Pub. No.: US 2024/0276640 A1
(43) Pub. Date: Aug. 15, 2024

(54) CIRCUIT BOARD, ELECTRONIC COMPONENT PACKAGE INCLUDING THE SAME, AND MANUFACTURING METHOD THEREOF

(71) Applicant: SAMSUNG ELECTRO-MECHANICS CO., LTD., Suwon-si (KR)

(72) Inventors: Young-Gon Kim, Suwon-si (KR); Hokwon Yoon, Suwon-si (KR); Eunseok Kang, Suwon-si (KR)

(73) Assignee: SAMSUNG ELECTRO-MECHANICS CO., LTD., Suwon-si (KR)

(21) Appl. No.: 18/386,053

(22) Filed: Nov. 1, 2023

(30) Foreign Application Priority Data
Feb. 9, 2023 (KR) 10-2023-0017567

(51) Int. Cl. H05K 1/11; H05K 1/02; H05K 3/40

(52) U.S. Cl. CPC H05K 1/111; H05K 1/0254; H05K 3/4015; H05K 2201/0203; H05K 2201/099

(57) ABSTRACT

An electronic component package according to an embodiment includes a circuit board including an insulating layer, a circuit wiring disposed inside the insulating layer, a plurality of first conductive pads disposed in a first region on the insulating layer and connected to the circuit wiring, an auxiliary pad disposed over the first conductive pad and having a diameter smaller than that of the first conductive pad, and a solder resist layer disposed over the insulating layer, having a first opening overlapping the first region, and spaced apart from the auxiliary pad; an electronic component spaced apart from the solder resist layer and disposed over the first opening; and a conductive adhesive member electrically connecting the auxiliary pad and the electronic component.

### CROSS-REFERENCE TO RELATED APPLICATION

This application claims priority to and the benefit of Korean Patent Application No. 10-2023-0017567 filed in the Korean Intellectual Property Office on Feb. 9, 2023, the entire contents of which are incorporated herein by reference.

### BACKGROUND

### 1. Technical Field

The present disclosure relates to a circuit board, an electronic component package including the same, and a manufacturing method thereof.

### 2. Description of the Related Art

Recently, with the development of electronic devices, the complexity of a design structure is increasing as the functions of the electronic devices are advanced. As the design structure becomes more complex, components for more functions are being mounted on a circuit board. To this end, as a double-sided package structure is being developed, efforts are being made to reduce a thickness of a package.

In order to reduce the thickness of the package, a thickness of a conductive bump of a die is reduced, but in this case, it may be difficult to secure a space between the die and the circuit board. Therefore, it is not easy to fill an underfill in a space between the die and the circuit board.

Also, since solder adhered to a conductive pad of the circuit board spreads due to pressing force and heat, when the space between the die and the circuit board is narrow, the solder is likely to short-circuit adjacent conductive pads.

The above information disclosed in this Background section is only for enhancement of understanding of the background of the disclosure, and therefore it may contain information that does not form the related art that is already known in this country to a person of ordinary skill in the art.

### SUMMARY

The present disclosure has been made in an effort to provide a circuit board capable of reducing an overall thickness of an electronic component package while preventing a short-circuit phenomenon between an auxiliary adhesive member and a conductive pad, an electronic component package including the same, and a manufacturing method thereof.

However, problems to be solved by the embodiments are not limited to the above-described problems and may be variously extended in the range of technical ideas included in the embodiments.

An embodiment of the present disclosure provides a circuit board including: an insulating layer; a circuit wiring disposed inside the insulating layer; a plurality of first conductive pads disposed in a first region on the insulating layer and connected to the circuit wiring; an auxiliary pad disposed over at least one of the plurality of first conductive pads and having a diameter smaller than that of the at least one of the plurality of first conductive pads; and a solder resist layer disposed on the insulating layer, having a first opening overlapping the first region, and spaced apart from the auxiliary pad.

The plurality of first conductive pads may not contact the solder resist layer.

Another embodiment of the present disclosure provides an electronic component package including: a circuit board including an insulating layer, a circuit wiring disposed inside the insulating layer, a plurality of first conductive pads disposed in a first region on the insulating layer and connected to the circuit wiring, an auxiliary pad disposed over at least one of the plurality of first conductive pads and having a diameter smaller than that of the at least one of the plurality of first conductive pads, and a solder resist layer disposed on the insulating layer, having a first opening overlapping the first region, and spaced apart from the auxiliary pad; an electronic component spaced apart from the solder resist layer and disposed over the first opening; and a conductive adhesive member electrically connecting the auxiliary pad and the electronic component.

The conductive adhesive member may include: a conductive bump transmitting an electrical signal of the electronic component; and an auxiliary adhesive member attaching the auxiliary pad and the conductive bump to each other.

A diameter of the conductive bump may be smaller than that of at least one first conductive pad among the plurality of first conductive pads.

The plurality of first conductive pads may not contact the solder resist layer.

The electronic component package may further include an underfill filling between the electronic component and an upper surface of the insulating layer, wherein the underfill may contact a side surface of at least one first conductive pad among the plurality of first conductive pads.

A side portion of the auxiliary pad may have an undercut.

The auxiliary adhesive member may include: a first adhesive part disposed between the auxiliary pad and the conductive bump and a second adhesive part extending from the first adhesive part along the side portion of the auxiliary pad to fill the undercut.

The circuit board may further include a plurality of second conductive pads disposed in a second region on a portion on the insulating layer different from the first region, the plurality of second conductive pads are connected to the circuit wiring, and the solder resist layer may have a second opening overlapping the plurality of second conductive pads.

The underfill may not contact a side surface of at least one second conductive pad among the plurality of second conductive pads.

A shortest gap between a lower surface of the electronic component and an upper surface of the insulating layer may be longer than a shortest gap between an extension line along the lower surface of the electronic component and an upper surface of the solder resist layer in the second region.

Yet another embodiment of the present disclosure provides a method of manufacturing an electronic component package including: forming an insulating layer having a circuit wiring disposed therein, forming a plurality of first conductive pads in a first region on the insulating layer, the plurality of first conductive pads is connected to the circuit wiring; forming a solder resist layer over the insulating layer, the solder resist layer has a first opening overlapping the first region; forming an auxiliary pad, which has a diameter smaller than that of at least one of the plurality of first conductive pads and is spaced apart from the solder resist layer, over the at least one of the plurality of first conductive pads; and electrically connecting the auxiliary pad and an electronic component via a conductive adhesive member.

The method may further include positioning electronic component on the first opening while being spaced apart from the solder resist layer, and filling an underfill between the electronic component and an upper surface of the insulating layer, wherein the underfill may contact a side surface of at least one first conductive pad among the plurality of first conductive pads.

The method may further include forming a plurality of second conductive pads in a second region on a portion on the insulating layer different from the first region while forming the plurality of first conductive pads, the plurality of second conductive pads may be connected to the circuit wiring, wherein the underfill may not contact a side surface of at least one second conductive pad among the plurality of second conductive pads.

According to embodiments of the present disclosure, it is possible to secure a sufficient gap between an electronic component and an upper surface of an insulating layer by positioning an electronic component in an opening formed by removing a portion of a solder resist layer. Therefore, since it is not necessary to reduce a thickness of a conductive bump, it is possible to prevent a short-circuit phenomenon between an auxiliary adhesive member and a conductive pad, which is easy to occur when the thickness of the conductive bump is reduced.

In addition, since an auxiliary pad having a smaller diameter than that of a conductive pad is formed on the conductive pad and the auxiliary pad adheres to an auxiliary adhesive member disposed in an opening of a solder resist layer, the auxiliary adhesive member is spaced apart from adjacent conductive pads by a predetermined gap, so it is possible to minimize the risk that the auxiliary adhesive member is short-circuited with the adjacent conductive pads.

In addition, by positioning an electronic component in an opening formed by removing a portion of a solder resist layer, it is possible to reduce an overall thickness of an electronic component package.

However, it is obvious that the effects of the embodiments are not limited to the above-described effects, and may be variously extended without departing from the spirit and scope of the present disclosure.

### BRIEF DESCRIPTION OF THE DRAWINGS

FIG. 1 is a plan view of an electronic component package according to an embodiment.

FIG. 2 is a cross-sectional view taken along line II-II′ in FIG. 1.

FIG. 3 is an enlarged cross-sectional view of a portion of FIG. 2.

FIGS. 4 and 5 are cross-sectional views sequentially illustrating a method of manufacturing an electronic component package according to an embodiment.

FIG. 6 is an enlarged cross-sectional view of an electronic component package according to another embodiment.

### DETAILED DESCRIPTION

Hereinafter, embodiments of the present disclosure will be described in detail with reference to the accompanying drawings so that those skilled in the art to which the present disclosure pertains may easily practice the present disclosure. However, the present disclosure may be implemented in various different forms and is not limited to embodiments provided herein.

Portions unrelated to the description will be omitted in order to obviously describe the present disclosure, and similar components will be denoted by the same or similar reference numerals throughout the present specification.

Further, it should be understood that the accompanying drawings are provided only in order to allow embodiments of the present disclosure to be easily understood, and the spirit of the present disclosure is not limited by the accompanying drawings, but includes all the modifications, equivalents, and substitutions included in the spirit and the scope of the present disclosure.

In addition, the size and thickness of each component illustrated in the drawings are arbitrarily indicated for convenience of description, and the present disclosure is not necessarily limited to the illustrated those. In the drawings, the thickness of layers, films, panels, regions, etc., are exaggerated for clarity. In addition, in the accompanying drawings, thicknesses of some of layers and regions have been exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, when an element is referred to as being “on” a reference element, it can be disposed on or beneath the reference element, and is not necessarily disposed on the reference element in an opposite direction to gravity.

In addition, unless explicitly described to the contrary, the word “comprise”, and variations such as “comprises” or “comprising”, will be understood to imply the inclusion of stated elements but not the exclusion of any other elements.

Further, throughout the specification, the word “plan view” refers to a view when a target is viewed from the top, and the word “cross-sectional view” refers to a view when a cross section of a target taken along a vertical direction is viewed from the side.

Also, throughout the specification, when it is said to be “connected”, this does not mean that two or more components are directly connected, but means that two or more components are indirectly connected through another component, that two or more components are physically connected as well as electrically connected, or that two or more components are referred to by different names depending on their location or function, but are integral.

Hereinafter, embodiments and modifications in the present disclosure will be described in detail with reference to the drawings.

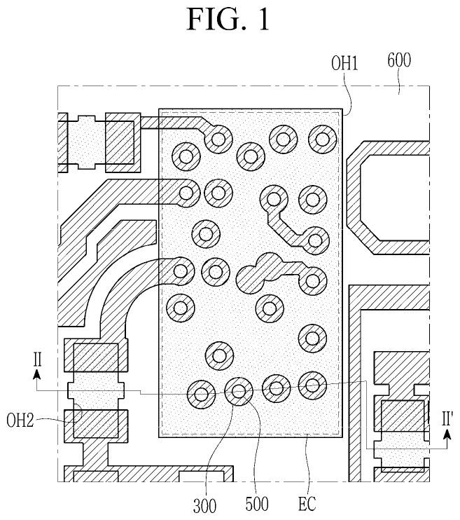

Referring to FIGS. 1 to 3, a circuit board and an electronic component package including the same according to an embodiment will be described.

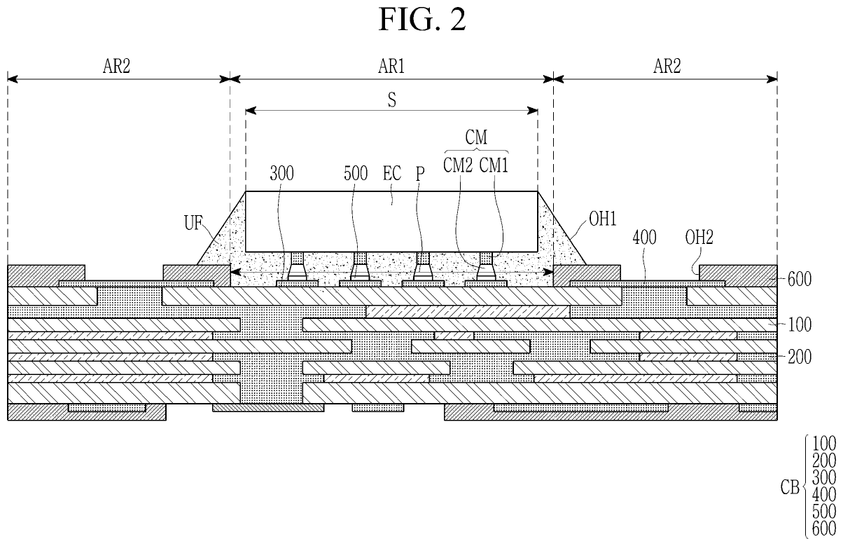

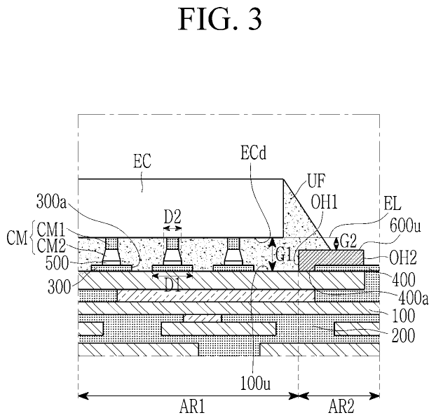

FIG. 1 is a plan view of an electronic component package according to an embodiment, FIG. 2 is a cross-sectional view taken along line II-II′ of FIG. 1, and FIG. 3 is an enlarged cross-sectional view of a portion of FIG. 2.

As illustrated in FIGS. 1 to 3, an electronic component package according to an embodiment includes a circuit board CB, an electronic component EC, a conductive adhesive member CM, and an underfill UF.

The circuit board CB may include an insulating layer 100, a circuit wiring 200, a plurality of first conductive pads 300, a plurality of second conductive pads 400, an auxiliary pad 500, and a solder resist layer 600.

The insulating layer 100 may include a thermosetting resin such as epoxy resin or polyimide, a thermoplastic resin such as polyethylene (PE), polycarbonate (PC), or polyvinyl chloride (PVC), or the like.

The circuit wiring 200 may be disposed inside the insulating layer 100. The circuit wiring 200 may transmit electrical signals. The circuit wiring 200 may be disposed in various patterns and may be disposed by being divided into a plurality of layers. In this embodiment, a structure in which circuit wirings of five layers are connected through vias is illustrated, but the structure is not necessarily limited thereto, and circuit wirings of various numbers of layers are possible.

The circuit wiring 200 may include a conductive material such as copper (Cu), aluminum (Al), silver (Ag), tin (Sn), gold (Au), nickel (Ni), lead (Pb), titanium (Ti), or alloys thereof.

The plurality of first conductive pads 300 may be disposed in a first region AR1 on the insulating layer 100 and connected to the circuit wiring 200. The first region AR1 over the insulating layer 100 may be a region in which the electronic component EC is disposed. The plurality of first conductive pads 300 may include a conductive material such as copper (Cu), gold (Au), silver (Ag), or a double layer of nickel (Ni)/gold (Au).

The plurality of second conductive pads 400 may be disposed in a second region AR2 over the insulating layer 100 and connected to the circuit wiring 200. The second region AR2 over the insulating layer 100 may be a region in which the electronic component EC is not disposed. The plurality of second conductive pads 400 may be made of the same material as the plurality of first conductive pads 300, and may include a conductive material such as copper (Cu), gold (Au), silver (Ag), or a double layer of nickel (Ni)/gold (Au).

The auxiliary pad 500 may be disposed on the first conductive pad 300. The auxiliary pad 500 may have a smaller diameter D2 than a diameter D1 of the first conductive pad 300.

The solder resist layer 600 may be disposed on the insulating layer 100 to cover the insulating layer 100. The solder resist layer 600 may include a first opening OH1 overlapping the first region AR1 of the insulating layer 100 and a second opening OH2 overlapping the second conductive pad 400 of the insulating layer 100. An upper surface of the first region of the insulating layer 100 may be exposed to the outside through the first opening OH1. The solder resist layer 600 may include an insulating material such as solder resist.

Here, the first conductive pad 300 and the auxiliary pad 500 disposed in the first opening OH1 formed by removing a portion of the solder resist layer 600 may not contact the solder resist layer 600.

The electronic component EC may be spaced apart from the solder resist layer 600 and disposed on the first opening OH1. A size of the electronic component EC may be smaller than that of the first opening OH1. That is, a length S of one side of the electronic component EC may be smaller than a length P of one side of the first opening OH1. The electronic component EC may be an integrated circuit die in which several hundred to several million or more elements are integrated in a single chip. For example, the electronic component (EC) may be a processor chip such as a central processor (e.g., CPU), a graphics processor (e.g., GPU), a field programmable gate array (FPGA), a digital signal processor, a cryptographic processor, a microprocessor, and a microcontroller, and specifically, may be an application processor (AP), but is not limited thereto, and may also be a memory such as other volatile memory (e.g., DRAM), non-volatile memory (e.g., ROM), or flash memory, or a logic such as an analog-to-digital converter or an application-specific IC (ASIC).

In this case, a shortest gap G1 between a lower surface ECd of the electron component EC and an upper surface 100u of the insulating layer 100 in the first opening OH1 of the solder resist layer 600 disposed in the first region AR1 may be longer than a shortest gap G2 between a virtual extension line EL of the lower surface ECd of the electronic component EC and an upper surface 600u of the solder resist layer 600 in the second region AR2. Accordingly, a sufficient gap may be secured between the electronic component EC and the upper surface 100u of the insulating layer 100. The shortest gaps G1 and G2 may be measured using techniques such as optical microscopy and electron microscopy. Other methods and/or tools appreciated by one of ordinary skill in the art, even if not described in the present disclosure, may also be used.

The conductive adhesive member CM may electrically connect the auxiliary pad 500 and the electronic component EC.

The conductive adhesive member CM may include a conductive bump CM1 and an auxiliary adhesive member CM2.

The conductive bump CM1 may be installed on a signal line of the electronic component EC to transmit an electrical signal of the electronic component EC. The conductive bump CM1 has a pillar shape, and a diameter of the conductive bump CM1 may be substantially similar to the diameter D2 of the auxiliary pad 500 and smaller than the diameter D1 of the first conductive pad 300. The conductive bump CM1 may include a conductive material such as copper (Cu), aluminum (Al), silver (Ag), tin (Sn), gold (Au), nickel (Ni), lead (Pb), titanium (Ti), or alloys thereof. The diameter of the conductive bump CM1, the diameter D2 of the auxiliary pad 500, and the diameter D1 of the first conductive pad 300 may be measured using techniques such as optical microscopy and electron microscopy. Other methods and/or tools appreciated by one of ordinary skill in the art, even if not described in the present disclosure, may also be used.

The auxiliary adhesive member CM2 may be disposed between the conductive bump CM1 and the auxiliary pad 500 to attach the conductive bump CM1 and the auxiliary pad 500 to each other, thereby improving adhesion and conductivity. The auxiliary adhesive member CM2 may include a solder and the like.

In this way, the electronic component package according to the embodiment is disposed over the first conductive pad 300, and the auxiliary pad 500 having the smaller diameter than that of the first conductive pad 300 may contact the auxiliary adhesive member CM2 disposed in the first opening OH1 of the solder resist layer, thereby minimizing the risk that the auxiliary adhesive member CM2 is short-circuited with the adjacent first conductive pads 300 adjacent to each other at a predetermined gap. That is, when the auxiliary adhesive member CM2 spreads between the conductive bump CM1 and the auxiliary pad 500 by the press force and heat, since the auxiliary adhesive member CM2 spreads in a border of the auxiliary pad 500, it is possible to prevent the auxiliary adhesive member CM2 from spreading to the first conductive pads 300 adjacent to each other at a predetermined gap.

In addition, by positioning the electronic component EC in the first opening OH1 formed by removing a portion of the solder resist layer 600, it is possible to secure a sufficient gap between the electronic component EC and the upper surface of the insulating layer 100. Therefore, since it is not necessary to reduce the thickness of the conductive bump CM1, it is possible to prevent the short-circuit phenomenon between the auxiliary adhesive member CM2 and the first conductive pad 300, which is easy to occur when the thickness of the conductive bump CM1 is reduced.

In addition, by positioning the electronic component EC in the first opening OH1 formed by removing a portion of the solder resist layer 600, it is possible to reduce the overall thickness of the electronic component package.

The underfill UF may fill the upper surface 100U between the electronic component EC and the insulating layer 100, thereby fixing the electronic component EC. The underfill UF may directly contact a side surface 300a of the first conductive pad 300. Therefore, the electronic component EC may be more strongly bonded to a circuit board CB. In this case, since a side surface 400a of the second conductive pad 400 is covered with the solder resist layer 600, the underfill UF does not contact the side surface 400a of the second conductive pad 400.

In addition, since there is the sufficient gap between the electronic component EC and the upper surface 100u of the insulating layer 100, the underfill UF may be easily filled between the electronic component EC and the upper surface 100u of the insulating layer 100. Therefore, the electronic component EC may be more strongly bonded to the circuit board CB using the underfill UF.

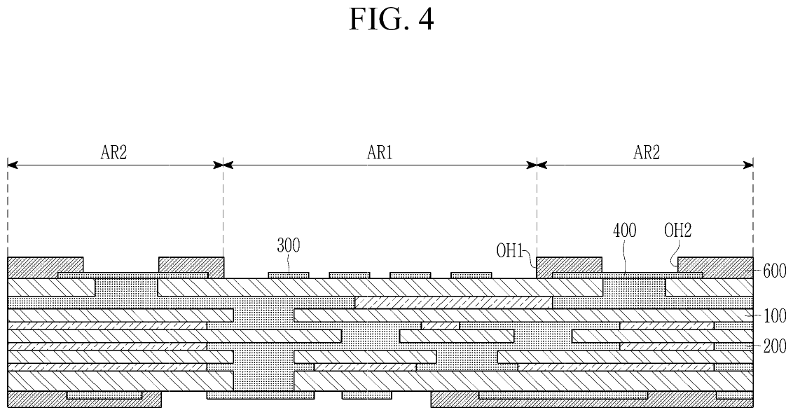

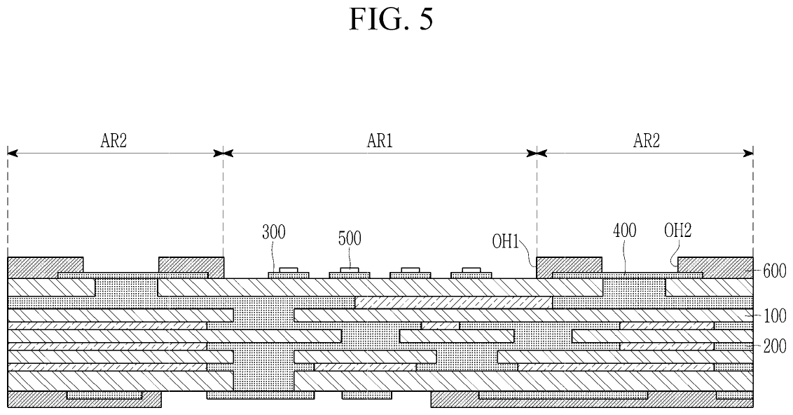

Then, with reference to FIGS. 4 and 5 along with FIGS. 1 to 3, a method of manufacturing an electronic component package according to an embodiment will be described in detail.

FIGS. 4 and 5 are cross-sectional views sequentially illustrating a method of manufacturing an electronic component package according to an embodiment.

As illustrated in FIG. 4, the insulating layer 100 has the circuit wiring 200 disposed therein. In addition, the plurality of first conductive pads 300 connected to the circuit wiring 200 is formed in the first region AR1 above the insulating layer 100. The plurality of first conductive pads 300 are formed, and at the same time, the plurality of second conductive pads 400 connected to the circuit wiring 200 are formed in the second region AR2 over the insulating layer 100. In addition, the solder resist layer 600 having the first opening OH1 overlapping the first region AR1 is formed over the insulating layer 100.

As illustrated in FIG. 5, the auxiliary pad 500 having a smaller diameter D2 than the diameter D1 of the first conductive pad 300 is formed on the first conductive pad 300. Here, the first conductive pad 300 and the auxiliary pad 500 may not contact the solder resist layer 600.

As illustrated in FIG. 1, the auxiliary pad 500 and the electronic component EC are electrically connected using the conductive adhesive member CM. In this case, the electronic component EC may be spaced apart from the solder resist layer 600 and disposed on the first opening OH1. In addition, the underfill UF may be filled between the electronic component EC and the upper surface of the insulating layer 100. The underfill UF may directly contact the side surface 300a of the first conductive pad 300. Therefore, the electronic component EC may be more strongly bonded to the circuit board CB.

Meanwhile, in the above embodiment, the auxiliary adhesive member may be disposed only between the conductive bump and the auxiliary pad, but other embodiments in which the auxiliary adhesive member extends along the side portion of the auxiliary pad are also possible.

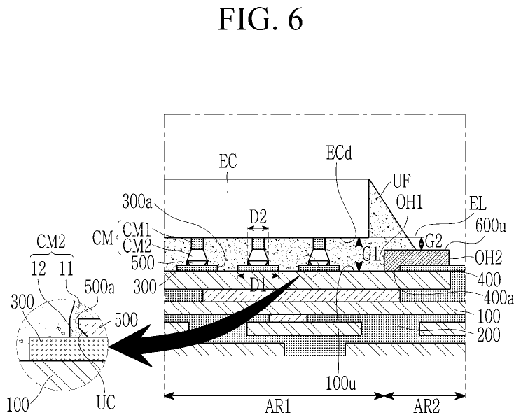

Hereinafter, an electronic component package according to another embodiment will be described in detail with reference to FIG. 6 along with FIGS. 1 to 3.

FIG. 6 is an enlarged cross-sectional view of an electronic component package according to another embodiment.

Another embodiment illustrated in FIG. 6 is substantially the same as the embodiment illustrated in FIGS. 1 to 3 except for only the structures of the auxiliary adhesive member and the auxiliary pad, and therefore, repeated descriptions thereof will be omitted.

As illustrated in FIGS. 2 and 6, an electronic component package according to another embodiment includes a circuit board CB, an electronic component EC, a conductive adhesive member CM, and an underfill UF.

The circuit board CB may include an insulating layer 100, a circuit wiring 200, a plurality of first conductive pads 300, a plurality of second conductive pads 400, an auxiliary pad 500, and a solder resist layer 600.

The auxiliary pad 500 may be disposed on the first conductive pad 300. The auxiliary pad 500 may have a smaller diameter D2 than a diameter D1 of the first conductive pad 300. A side portion 500a of the auxiliary pad 500 may have an undercut UC. That is, the undercut UC by over-etching may be formed on a portion adjacent to the upper surface of the first conductive pad 300 among the side portions 500a of the auxiliary pad 500.

The conductive adhesive member CM may include a conductive bump CM1 and an auxiliary adhesive member CM2. The auxiliary adhesive member CM2 may include a first adhesive part 11 and a second adhesive part 12.

The first adhesive part 11 may be disposed between the conductive bump CM1 and the auxiliary pad 500 to attach the conductive bump CM1 and the auxiliary pad 500 to each other, thereby improving adhesion and conductivity.

The second adhesive part 12 may extend from the first adhesive part 11 along the side portion 500a of the auxiliary pad 500 to fill the undercut UC of the auxiliary pad 500. The second adhesive part 12 may further improve the adhesion between the conductive bump CM1 and the auxiliary pad 500.

Although preferred embodiments of the present disclosure have been described above, the present disclosure is not limited thereto, and the present disclosure can be variously modified within the scope of the claims, the detailed description of the disclosure, and the appended drawings, and it is natural that various modifications also fall within the scope of the present disclosure.

What is claimed is:

1. A circuit board, comprising:
an insulating layer;
a circuit wiring disposed inside the insulating layer;
a plurality of first conductive pads disposed in a first region on the insulating layer and connected to the circuit wiring;
an auxiliary pad disposed over at least one of the plurality of first conductive pads and having a diameter smaller than that of the at least one of the plurality of first conductive pads; and
a solder resist layer disposed over the insulating layer, having a first opening overlapping the first region, and spaced apart from the auxiliary pad.

2. The circuit board of claim 1, wherein:
the plurality of first conductive pads do not contact the solder resist layer.

3. The circuit board of claim 1, wherein:
the auxiliary pad does not contact the solder resist layer.

4. The circuit board of claim 3, wherein:
a side portion of the auxiliary pad has an undercut.

5. The circuit board of claim 4, wherein:
the circuit board further includes:
a plurality of second conductive pads disposed in a second region on a portion on the insulating layer different from the first region, the plurality of second conductive pads are connected to the circuit wiring.

6. The circuit board of claim 5, wherein:
the solder resist layer has a second opening overlapping the plurality of second conductive pads.

7. An electronic component package, comprising:
a circuit board including
an insulating layer,
a circuit wiring disposed inside the insulating layer,
a plurality of first conductive pads disposed in a first region on the insulating layer and connected to the circuit wiring,
an auxiliary pad disposed over at least one of the plurality of first conductive pads and having a diameter smaller than that of the at least one of the plurality of first conductive pads, and
a solder resist layer disposed over the insulating layer, having a first opening overlapping the first region, and spaced apart from the auxiliary pad;
an electronic component spaced apart from the solder resist layer and disposed over the first opening; and
a conductive adhesive member electrically connecting the auxiliary pad and the electronic component.

8. The electronic component package of claim 7, wherein:
the conductive adhesive member includes:
a conductive bump transmitting an electrical signal of the electronic component; and
an auxiliary adhesive member attaching the auxiliary pad and the conductive bump to each other.

9. The electronic component package of claim 8, wherein:
a diameter of the conductive bump is smaller than that of at least one first conductive pad among the plurality of first conductive pads.

10. The electronic component package of claim 8, wherein:
the plurality of first conductive pads do not contact the solder resist layer.

11. The electronic component package of claim 8, further comprising:
an underfill filling between the electronic component and an upper surface of the insulating layer,
wherein the underfill contacts a side surface of at least one first conductive pad among the plurality of first conductive pads.

12. The electronic component package of claim 10, wherein:
a side portion of the auxiliary pad has an undercut.

13. The electronic component package of claim 12, wherein:
the auxiliary adhesive member includes:
a first adhesive part disposed between the auxiliary pad and the conductive bump; and
a second adhesive part extending from the first adhesive part along the side portion of the auxiliary pad to fill the undercut.

14. The electronic component package of claim 11, wherein:
the circuit board further includes:
a plurality of second conductive pads disposed in a second region on a portion on the insulating layer different from the first region, the plurality of second conductive pads are connected to the circuit wiring; and
the solder resist layer has a second opening overlapping the plurality of second conductive pads.

15. The electronic component package of claim 14, wherein:
the underfill does not contact a side surface of at least one second conductive pad among the plurality of second conductive pads.

16. The electronic component package of claim 14, wherein:
a shortest gap between a lower surface of the electronic component and an upper surface of the insulating layer is longer than a shortest gap between an extension line along the lower surface of the electronic component and an upper surface of the solder resist layer in the second region.

17. A method of manufacturing an electronic component package, comprising:
forming an insulating layer having a circuit wiring disposed therein;
forming a plurality of first conductive pads in a first region on the insulating layer, the plurality of first conductive pads is connected to the circuit wiring;
forming a solder resist layer over the insulating layer, the solder resist layer has a first opening overlapping the first region;
forming an auxiliary pad, which has a diameter smaller than that of at least one of the plurality of first conductive pads and is spaced apart from the solder resist layer, over the at least one of the plurality of first conductive pads; and
electrically connecting the auxiliary pad and an electronic component via a conductive adhesive member.

18. The method of claim 17, further comprising:
positioning the electronic component over the first opening while being spaced apart from the solder resist layer; and
filling an underfill between the electronic component and an upper surface of the insulating layer,
wherein the underfill contacts a side surface of at least one first conductive pad among the plurality of first conductive pads.

19. The method of claim 18, further comprising:
forming a plurality of second conductive pads in a second region on a portion on the insulating layer different from the first region while forming the plurality of first conductive pads, the plurality of second conductive pads is connected to the circuit wiring,
wherein the underfill does not contact a side surface of at least one second conductive pad among the plurality of second conductive pads.
